(19) United States
(12) Patent Application Publication
(10) Pub. No.: US 2018/0040534 A1
(43) Pub. Date: Feb. 8, 2018

(54) SEMICONDUCTOR MODULE

(71) Applicant: FUJI ELECTRIC CO., LTD., Kawasaki-shi (JP)

(72) Inventor: Fumio SHIGETA, Okaya-city (JP)

(73) Assignee: FUJI ELECTRIC CO., LTD., Kawasaki-shi (JP)

(21) Appl. No.: 15/666,553

(22) Filed: Aug. 1, 2017

(30) Foreign Application Priority Data
Aug. 3, 2016 (JP) 2016-152444

(51) Int. Cl. H01L 23/373; H01L 23/31; H01L 23/367; H01L 23/055

(52) U.S. Cl. CPC H01L 23/3735; H01L 23/055; H01L 23/3114; H01L 23/3672

(57) ABSTRACT

A semiconductor module includes a first recessed portion and a second recessed portion formed in an insulating plate at positions close to a first long side and a second long side opposite to the first long side, and a first protruding portion and a second protruding portion formed on a case at bottom surfaces of a first side wall and a second side wall opposite to the first side wall. The first protruding portion and the second protruding portion are engaged with the first recessed portion and the second recessed portion with bonding adhesive in between. Thereby, a joined area between the insulating plate and the containment unit (case) increases. Accordingly, joining force between the insulating plate and the containment unit (case) increases to prevent generation of a gap between the insulating plate and the containment unit (case).

### CROSS-REFERENCE TO RELATED APPLICATION

This application is based upon and claims the benefit of priority of the prior Japanese Patent Application No. 2016-152444, filed on Aug. 3, 2016, the entire contents of which are incorporated herein by reference.

### BACKGROUND OF THE INVENTION

### 1. Field of the Invention

The embodiments discussed herein relate to a semiconductor module.

### 2. Background of the Related Art

A semiconductor module includes a multi-layer substrate, a power semiconductor element mounted on the multi-layer substrate, and a plastic case located on the multi-layer substrate to contain the power semiconductor element. Encapsulation resin fills the plastic case of the semiconductor module to encapsulate the power semiconductor element and other components. An upper lid is mounted on the plastic case.

See, for example, Japanese Laid-open Patent Publication No. 2000-133769.

When voltage is applied to the power semiconductor element to drive the power semiconductor element, the power semiconductor element generates heat so as to cause heat stress in the multi-layer substrate to warp the multi-layer substrate. When the multi-layer substrate warps, a gap is created between the plastic case and the multi-layer substrate, and this gap allows the encapsulation resin to leak therethrough, thereby impairing the reliability of the semiconductor module.

### SUMMARY OF THE INVENTION

According to one aspect, there is provided a semiconductor module comprising a multi-layer substrate including an insulating plate being rectangular and including a front surface, a back surface opposite to the front surface, a first long side, a second long side opposite to the first long side, a first recessed portion located in the front surface along the first long side, and a second recessed portion located in the front surface along the second long side. The semiconductor module further includes a circuit plate located on a region inside a periphery portion of the insulating plate, the periphery portion including the first recessed portion and the second recessed portion, and a case including a first side wall, a second side wall opposite to the first side wall, a third side wall located between the first side wall and the second side wall, a fourth side wall opposite to the third side wall, a first protruding portion located on a bottom surface of the first side wall, a second protruding portion located on a bottom surface of the second side wall, and fixation portions located on the third side wall and the fourth side wall to fix a cooling unit on the back surface of the insulating plate, the case being located on the periphery portion with bonding adhesive in between. The semiconductor module further includes an encapsulation material that encapsulates the circuit plate in the case, wherein the first protruding portion is inserted in the first recessed portion, and the second protruding portion is inserted in the second recessed portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side view of a semiconductor device in a first embodiment;

FIG. 2 is a top view of a semiconductor device in the first embodiment;

FIG. 3 is a side view of a multi-layer substrate in the first embodiment;

FIG. 4 is a top view of a multi-layer substrate in the first embodiment;

FIG. 5 is a cross-sectional view of a semiconductor device across an alternate long and short dash line Y-Y of FIG. 2;

FIG. 6 is a cross-sectional view of a semiconductor device across an alternate long and short dash line X-X of FIG. 1;

FIG. 7 is a side view of a semiconductor device of a comparison example; and

FIG. 8 is an enlarged view of a main part of a semiconductor device of a second embodiment.

### DETAILED DESCRIPTION OF THE INVENTION

In the following, embodiments will be described with reference to the drawings.

### First Embodiment

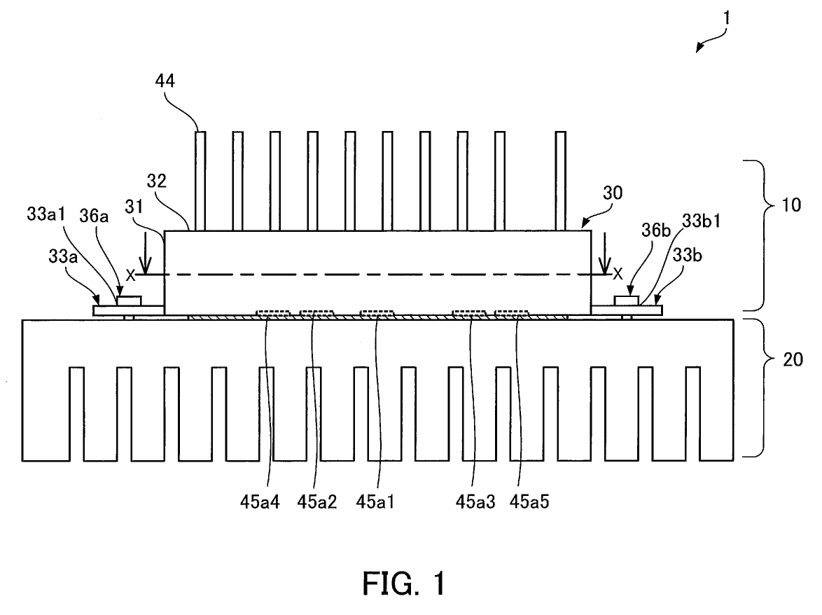

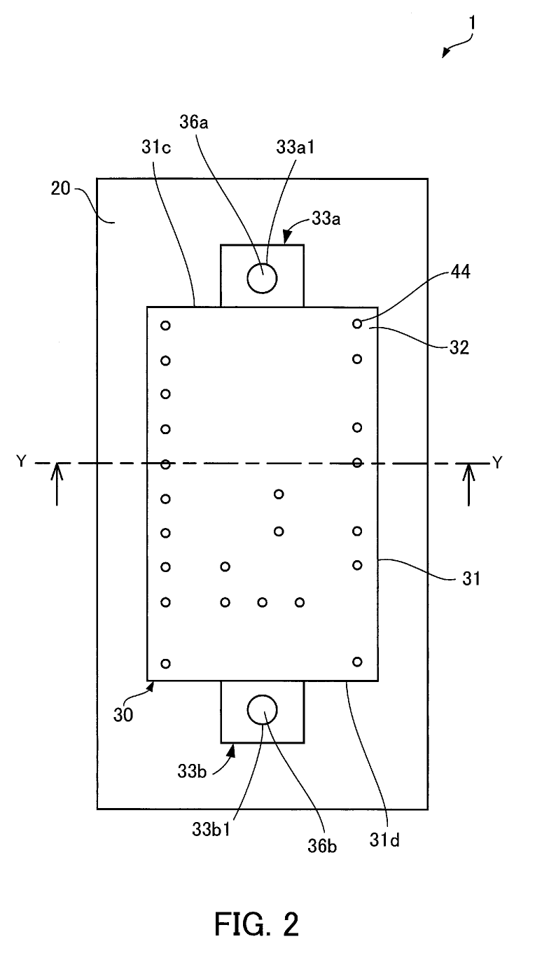

A semiconductor device of a first embodiment will be described with reference to FIGS. 1 and 2.

FIG. 1 is a side view of the semiconductor device in the first embodiment, and FIG. 2 is a top view of the semiconductor device in the first embodiment.

The semiconductor device 1 includes a semiconductor module 10 and a cooling unit 20 attached to the semiconductor module 10.

The semiconductor module 10 includes a multi-layer substrate (described later), a case 31, and encapsulation material (not illustrated) filling the case 31.

The case 31 with an upper lid 32 may compose a containment unit 30. The multi-layer substrate may be located inside the containment unit 30. A plurality of external connection terminals 44 of the multi-layer substrate protrude from the upper lid 32.

Also, a pair of side walls 31c and 31d (third and fourth side walls) of the case 31 are located opposite to each other and are provided with fixation portions 33a and 33b including screw holes 33a1 and 33b1 respectively. The cooling unit 20 is detachably fixed on the back surface of the semiconductor module 10 by using screws 36a and 36b that are inserted into the screw holes 33a1 and 33b1 respectively. Note that the detail of the case 31 will be described later.

The cooling unit 20 is made of aluminum, iron, silver, copper, or alloy thereof, which has high thermal conductivity, for example. The cooling unit 20 conducts the heat generated from the semiconductor module 10 and releases the heat to the ambience. The cooling unit 20 includes cooling fins illustrated in FIG. 1, for example. The cooling unit 20 is not limited to the cooling fins illustrated in FIG. 1, but may be a cooling device that circulates fluid inside the cooling device to cool the semiconductor module 10. The semiconductor module 10 may be provided directly on the cooling unit 20 and may be provided with heat conduction material, such as compound, in between.

In this semiconductor device 1, power semiconductor elements operate and generate heat, which is conducted to the cooling unit 20 and is released to ambience from the cooling unit 20. Thereby, the semiconductor module 10 is cooled.

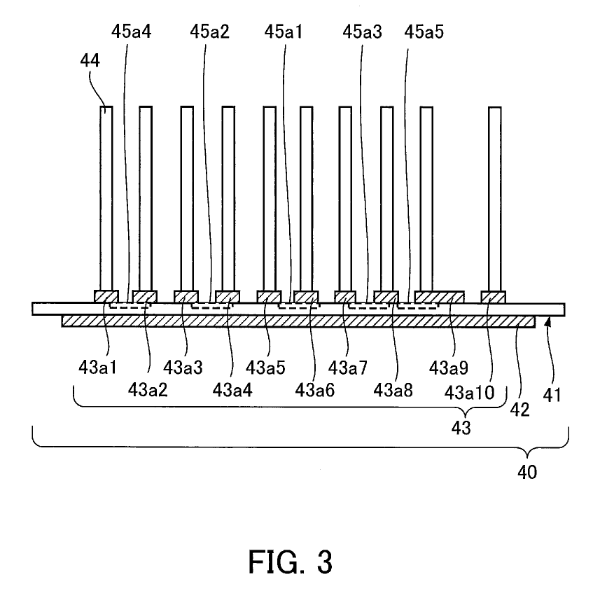

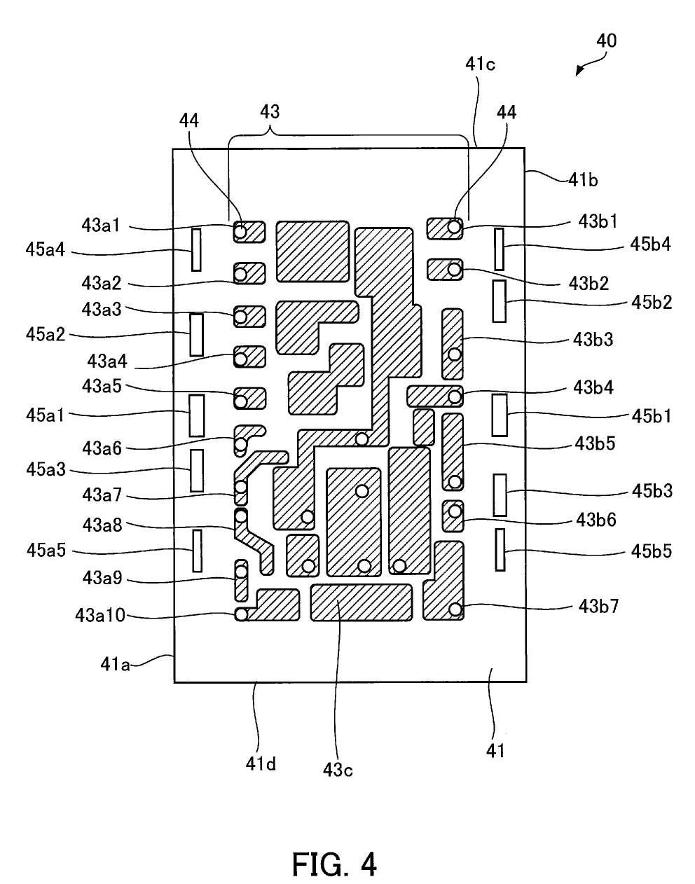

Next, the multi-layer substrate of the semiconductor module 10 will be described with reference to FIGS. 3 and 4.

FIG. 3 is a side view of the multi-layer substrate in the first embodiment, and FIG. 4 is a top view of the multi-layer substrate in the first embodiment.

The multi-layer substrate 40 includes an insulating plate 41 and a circuit plate 43. The insulating plate 41 may be rectangular and have a front surface and a back surface opposite to the front surface.

The multi-layer substrate 40 may include a circuit plate 43 located on the front surface of the insulating plate 41, a metal plate 42 located on the back surface of the insulating plate 41, and external connection terminals 44 provided on the circuit plate 43.

The thickness of the insulating plate 41 is 250 μm or more and 380 μm or less, for example. The insulating plate 41 is made of aluminum oxide, silicon nitride, or the like. The insulating plate 41 may include a long side 41a (first long side), a long side 41b (second long side) opposite to the long side 41a, and a periphery portion. The insulating plate 41 may further include a short side 41c and a short side 41d opposite to the short side 41c, between the long side 41a and the long side 41b. Recessed portions 45a1 to 45a5 (first recessed portions) are formed along the long side 41a (first long side) in the periphery portion of the front surface of the insulating plate 41. In the same way, recessed portions 45b1 to 45b5 (second recessed portions) are formed along the long side 41b (second long side) in the periphery portion of the front surface. The recessed portions 45a1 to 45a5 and 45b1 to 45b5 are formed with such sizes that the strength of the insulating plate 41 does not decrease significantly. Also, the recessed portions 45a1 to 45a5 and 45b1 to 45b5 are formed by continuously radiating laser on predetermined positions of the insulating plate 41, for example. The recessed portions 45a1 to 45a5 and 45b1 to 45b5 may be formed by molding, etching, or machining.

The metal plate 42 is provided on the entire back surface of the insulating plate 41 and is made of aluminum, iron, silver, copper, or alloy thereof, which have a high thermal conductivity, for example.

The circuit plate 43 may be located in a region inside the frame-shaped periphery portion of the insulating plate 41. The front surface of the insulating plate 41 may include the recessed portions 45a1 to 45a5 in the periphery portion between the circuit plate 43 and the long side 41a, and the recessed portions 45b1 to 45b5 in the periphery portion between the circuit plate 43 and the long side 41b. The circuit plate 43 may be made of metal, such as copper, having excellent electrical conductivity, for example. The circuit plate 43 may further include circuit patterns 43a1 to 43a10 and 43b1 to 43b7 provided along the respective long sides 41a and 41b of the insulating plate 41, and a plurality of circuit patterns 43c located inside the circuit patterns 43a1 to 43a10 and 43b1 to 43b7. Also, the external connection terminals 44 are located as appropriate and electrically connected to the respective circuit patterns 43a1 to 43a10 and 43b1 to 43b7, 43c.

Also, power semiconductor elements (not illustrated), such as an insulated gate bipolar transistor (IGBT), a metal oxide semiconductor field effect transistor (MOSFET), and a free wheeling diode (FWD), are located as appropriate on the circuit patterns 43a1 to 43a10 and 43b1 to 43b7, 43c. Wires and lead frames (not illustrated) electrically interconnect between the power semiconductor elements and the circuit patterns 43a1 to 43a10 and 43b1 to 43b7, 43c as appropriate.

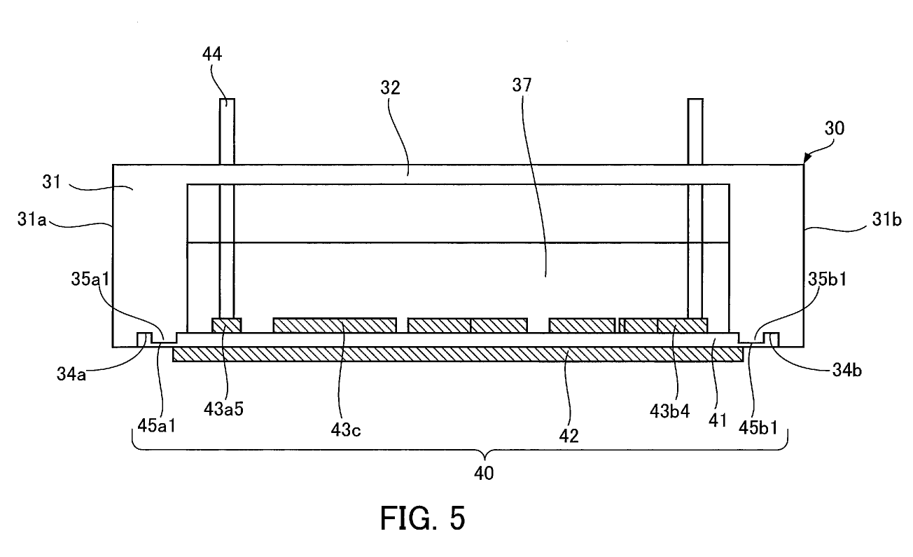

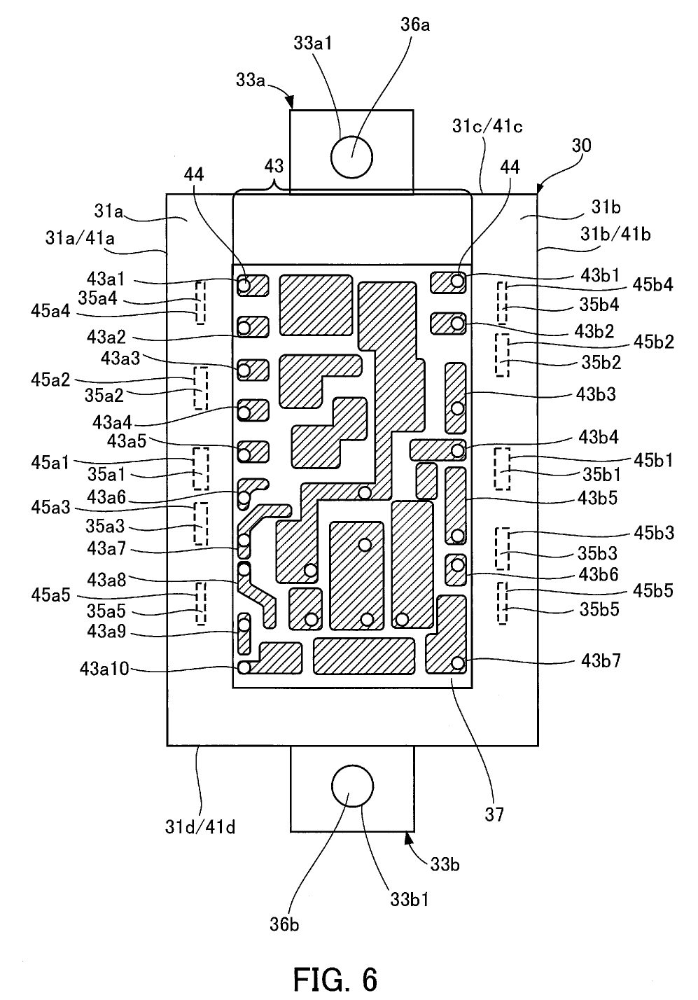

Next, the detail of the containment unit 30 will be described with reference to FIGS. 5 and 6.

FIG. 5 is a cross-sectional view of the semiconductor device across an alternate long and short dash line Y-Y of FIG. 2, and FIG. 6 is a cross-sectional view of the semiconductor device across an alternate long and short dash line X-X of FIG. 1.

Note that the cooling unit 20 is not depicted in FIG. 5 or 6.

The containment unit 30 includes the case 31 located on the multi-layer substrate 40 and the upper lid 32 that closes an opening of the case 31.

The case 31 is located along the periphery portion of the insulating plate 41 with bonding adhesive (not illustrated) in between, so as to surround the circuit plate 43. The periphery portion includes the recessed portions 45a1 to 45a5 and 45b1 to 45b5 of the insulating plate 41. The case 31 may be molded with resin.

The case 31 may have a box shape having a side wall 31a (first side wall), a side wall 31b (second side wall) opposite to the side wall 31a, a side wall 31c, and a side wall 31d opposite to the side wall 31c. The side wall 31c and the side wall 31d are located between the side wall 31a and the side wall 31b. The side walls 31a and 31b may have a substantially same length and be longer than the side walls 31c and 31d.

Protruding portions 35a1 to 35a5 (first protruding portions) are formed on a bottom surface 34a of the side wall 31a that faces the periphery portion of the insulating plate 41 at positions corresponding to the recessed portions 45a1 to 45a5 of the insulating plate 41. In the same way, protruding portions 35b1 to 35b5 (second protruding portions) are formed on a bottom surface 34b of the side wall 31b at positions corresponding to the recessed portions 45b1 to 45b5 of the insulating plate 41. In order to locate the case 31 along the periphery portion of the insulating plate 41 of the multi-layer substrate 40, the protruding portions 35a1 to 35a5 and 35b1 to 35b5 are inserted into the recessed portions 45a1 to 45a5 and 45b1 to 45b5, respectively. The protruding portions 35a1 to 35a5 and 35b1 to 35b5 may be press-fitted in the recessed portions 45a1 to 45a5 and 45b1 to 45b5, or alternatively may be bonded to the recessed portions 45a1 to 45a5 and 45b1 to 45b5 by bonding adhesive. Note that the protruding portions 35a1 to 35a5 and 35b1 to 35b5 may be formed integrally with the case 31, by creating an injection-molding die including shapes corresponding to the protruding portions 35a1 to 35a5 and 35b1 to 35b5 of the case 31.

Encapsulation material 37 fills the case 31 to encapsulate the circuit plate 43. The encapsulation material 37 may encapsulate the power semiconductor elements, the wires, and the external connection terminals 44 that are located on the circuit plate 43. Also, the fixation portions 33a and 33b including the screw holes 33a1 and 33b1 are formed at the center portions of the side walls 31c and 31d of the case 31, respectively.

Note that the encapsulation material 37 may be epoxy resin or silicone gel, for example.

The upper lid 32 is made of the same resin as the case 31 and is attached integrally to the upper end of the case 31 so as to close the opening of the case 31. Insertion holes (not illustrated) corresponding to the external connection terminals 44 are formed in the upper lid 32 to allow the external connection terminals 44 to be inserted therethrough. Also, a filling hole (not illustrated) through which the encapsulation material 37 is injected to fill the case 31 is formed as appropriate in the upper lid 32.

The semiconductor module 10 of the semiconductor device 1 is constructed by bringing the bottom surfaces 34a and 34b of the side walls 31a and 31b of the containment unit 30 (case 31) into contact with the periphery portion of the insulating plate 41 of the multi-layer substrate 40 with the bonding adhesive in between and filling the containment unit 30 with the encapsulation material 37 to encapsulate the circuit plate 43 and the components on the circuit plate 43.

Further, the semiconductor module 10 is mounted on the cooling unit 20, and the screws 36a and 36b are inserted through the screw holes 33a1 and 33b1 of the fixation portions 33a and 33b and screwed into the cooling unit 20, in order to fix the semiconductor module 10 to the cooling unit 20. In this way, the semiconductor device 1 illustrated in FIGS. 1 and 2 is assembled. The multi-layer substrate 40 is sandwiched and constrained between the case 31 and the cooling unit 20. In the semiconductor device 1, the fixation portions 33a and 33b are adjacent to the short sides 41c and 41d, and thus the short sides 41c and 41d are pressed on the cooling unit 20 more firmly than the long sides 41a and 41b of the multi-layer substrate 40.

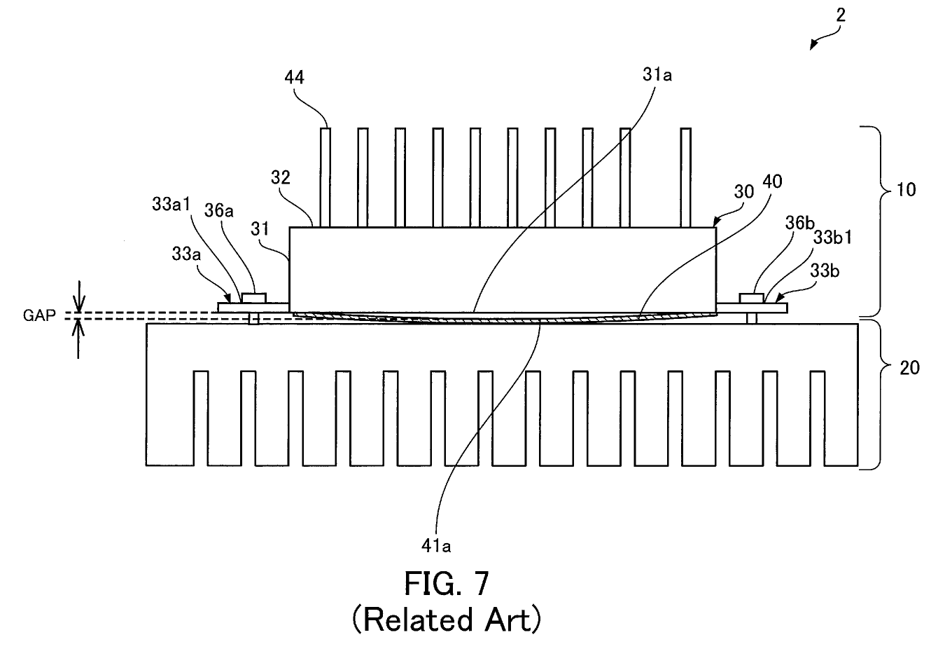

Here, a semiconductor device of a comparison example will be described with reference to FIG. 7.

FIG. 7 is a side view of the semiconductor device of the comparison example.

The semiconductor device 2 differs from the semiconductor device 1 of the first embodiment illustrated in FIGS. 1 and 2 in that the semiconductor device 2 is not provided with the recessed portions 45a1 to 45a5 and 45b1 to 45b formed in the insulating plate 41 and the protruding portions 35a1 to 35a5 and 35b1 to 35b5 formed on the bottom surfaces 34a and 34b of the case 31 of the semiconductor device 1. Except for these components, the semiconductor device 2 includes the same components as the semiconductor device 1.

In the semiconductor device 2 of this configuration, the power semiconductor elements are driven to generate heat, and the heat is conducted to the multi-layer substrate 40. In the multi-layer substrate 40, the insulating plate 41, the metal plate 42, and the circuit plate 43 deform due to the heat. In the multi-layer substrate 40, heat stress is generated from the difference between the linear expansion coefficients of the insulating plate 41, the metal plate 42, and the circuit plate 43, so that the multi-layer substrate 40 deforms and warps in a bowl shape, for example.

By the way, in the semiconductor device 2, the semiconductor module 10 is mounted on the cooling unit 20 and is fixed to the cooling unit 20 by using the screws 36a and 36b inserted through the screw holes 33a1 and 33b1 of the fixation portions 33a and 33b of the containment unit 30.

That is, the short sides 41c and 41d of the multi-layer substrate 40 are pressed by the respective screws 36a and 36b and the cooling unit 20 (refer to FIG. 6, for example).

In the semiconductor device 2, the multi-layer substrate 40 is forced to warp in a bowl shape by the heat stress caused by the heat generated by the power semiconductor elements. However, warpage in the shorter direction is suppressed, and the multi-layer substrate 40 deforms in a concave shape in the longitudinal direction (convex downwardly on the metal plate 42 side) as illustrated in FIG. 7.

In this state, the semiconductor device 2 has gaps between the long sides 41a and 41b of the multi-layer substrate 40 and the side walls 31a and 31b of the containment unit 30 (case 31) as illustrated in FIG. 7. In the semiconductor device 2, it is possible that the encapsulation material 37 filling the containment unit 30 leaks out of this gap, and that outside moisture enters the containment unit 30 from this gap.

In order to prevent this, the semiconductor device 1 is provided with the recessed portions 45a1 to 45a5 and 45b1 to 45b5 formed along the long sides 41a and 41b of the insulating plate 41 of the multi-layer substrate 40, as well as the protruding portions 35a1 to 35a5 and 35b1 to 35b5 formed along the bottom surfaces 34a and 34b of the side walls 31a and 31b of the containment unit 30 (case 31). The protruding portions 35a1 to 35a5 and 35b1 to 35b5 are inserted into the recessed portions 45a1 to 45a5 and 45b1 to 45b5 respectively, by bringing the bottom surfaces 34a and 34b of the containment unit 30 (case 31) into contact with the periphery portion of the insulating plate 41 of the multi-layer substrate 40. The protruding portions 35a1 to 35a5 and 35b1 to 35b5 may be press-fitted in the recessed portions 45a1 to 45a5 and 45b1 to 45b5, or alternatively may be bonded to the recessed portions 45a1 to 45a5 and 45b1 to 45b5 by bonding adhesive. The bottom surfaces 34a and 34b and the periphery portion of the insulating plate 41 may be bonded by bonding adhesive.

When the power semiconductor elements are driven by the voltage applied thereto and generate heat, the short side 41c and the short side 41d opposite to the short side 41c are pressed by the screws 36a and 36b and the cooling unit 20, and thus the multi-layer substrate 40 is forced to warp in a concave shape in the longitudinal direction (convex downwardly on the metal plate 42 side) as illustrated in FIG. 7.

However, in the semiconductor device 1, the protruding portions 35a1 to 35a5 and 35b1 to 35b5 of the containment unit 30 (case 31) are inserted into the recessed portions 45a1 to 45a5 and 45b1 to 45b5 of the insulating plate 41, and thereby the joined area between the insulating plate 41 and the containment unit 30 (case 31) increases. Accordingly, the semiconductor device 1 increases the joining force between the insulating plate 41 and the containment unit 30 (case 31), and thereby prevents generation of the gaps between the insulating plate 41 and the containment unit 30 (case 31).

Therefore, even when the multi-layer substrate 40 of the semiconductor device 1 is forced to warp in a concave shape in the longitudinal direction (convex downwardly on the metal plate 42 side) due to the heat stress, the generation of the gaps between the insulating plate 41 and the containment unit 30 (case 31) is prevented. The prevention of the gaps between the insulating plate 41 and the containment unit 30 (case 31) results in prevention of the outflow of the encapsulation material 37, such as silicone gel. Also, outside moisture is prevented from flowing into the containment unit 30 (case 31) and reaching the encapsulation material 37, such as epoxy resin. In this way, the semiconductor device 1 prevents the decrease of reliability.

As described with reference to FIG. 7, heat stress is generated in the multi-layer substrate 40 of the semiconductor device 2, while the short sides 41c and 41d are pressed by the screws 36a and 36b and the cooling unit 20, and thus the multi-layer substrate 40 warps in a concave shape in the longitudinal direction (convex downwardly on the metal plate 42 side).

The multi-layer substrate 40 warps in a concave shape in the longitudinal direction (convex downwardly on the metal plate 42 side), and therefore the gaps between the long sides 41a and 41b of the multi-layer substrate 40 and the side walls 31a and 31b of the containment unit 30 become widest around the center portions of the long sides 41a and 41b and become narrower toward the end portions of the long sides 41a and 41b.

In order to prevent the generation of the gaps between the long sides 41a and 41b of the multi-layer substrate 40 and the side walls 31a and 31b of the containment unit 30, it is preferable that the recessed portions 45a1 and 45b1 be provided around the center portions of the long sides 41a and 41b of the insulating plate 41, and that the protruding portions 35a1 and 35b1 be provided around the center portions of the side walls 31a and 31b of the case 31. In the semiconductor module 10, the recessed portions 45a1 and 45b1 and the protruding portions 35a1 and 35b1 may be located to face each other.

The joining force increases by additionally providing a plurality of recessed portions 45a2 to 45a5 and 45b2 to 45b5 in the insulating plate 41 and a plurality of protruding portions 35a2 to 35a5 and 35b2 to 35b5 in the case 31. Although the first embodiment is provided with the five recessed portions 45a1 to 45a5, the five recessed portions 45b1 to 45b5, the five protruding portions 35a1 to 35a5, and the five protruding portions 35b1 to 35b5, the number of recessed portions or protruding portions is not limited to five, but may be two to four or six or more. The recessed portions 45a2 and 45a4 and the recessed portions 45a3 and 45a5 may be located on both sides of the recessed portion 45a1. The recessed portions 45b2 and 45b4 and the recessed portions 45b3 and 45b5 may be located on both sides of the recessed portion 45b1. The recessed portions 45a1 to 45a5 may be aligned along a line, or may be arranged in a zig-zag manner. The recessed portions 45b1 to 45b5 may be arranged in the same manner.

Also, in the semiconductor device 2, the gaps between the long sides 41a and 41b of the multi-layer substrate 40 and the side walls 31a and 31b of the containment unit 30 become widest around the center portions of the long sides 41a and 41b and become narrower toward the end portions of the long sides 41a and 41b. That is, it is conceived that the heat stress generated in the multi-layer substrate 40 is larger around the center portions of the long sides 41a and 41b than at the end portions.

Therefore, in the semiconductor device 1, it is desirable to increase the joining force at the centers of the long sides 41a and 41b of the insulating plate 41. In order to achieve this, it is desirable that the recessed portions at the center portions of the insulating plate 41 and the protruding portions at the center portions of the case 31 have larger volumes than those at the end portions. The volumes of the recessed portions (and the protruding portions) increase from the end portions of the long sides 41a and 41b toward the center portions of the long sides 41a and 41b, thereby increasing the joined area and the joining force between the containment unit 30 (case 31) and the insulating plate 41.

In the first embodiment, with regard to the volumes of the recessed portions 45a1 to 45a5 and 45b1 to 45b5, the volumes of the recessed portions 45a1 and 45b1 formed at the center portions of the long sides 41a and 41b are larger than the volumes of the recessed portions 45a4, 45a5, 45b4, and 45b5 formed near the end portions of the long sides 41a and 41b.

For example, the recessed portions 45a1 to 45a5 and 45b1 to 45b5 have the same depths of approximately 190 μm, and the recessed portions 45a1 to 45a5 and 45b1 to 45b5 have the same length of approximately 2500 μm in the long side direction of the insulating plate 41. In this case, the widths of the recessed portions 45a1 and 45b1 in the short side direction of the insulating plate 41 are approximately 500 μm; the widths of the recessed portions 45a2, 45a3, 45b2, and 45b3 are approximately 400 μm; and the widths of the recessed portions 45a4, 45a5, 45b4, and 45b5 are approximately 300 μm.

Also, in the semiconductor device 1, the recessed portions 45a1 to 45a5 and 45b1 to 45b5 formed along the long sides 41a and 41b of the insulating plate 41 may be arranged to face the interspaces between the circuit patterns 43a1 to 43a10 and 43b1 to 43b7 of the circuit plate 43 provided along the long sides 41a and 41b of the insulating plate 41. Also, the protruding portions 35a1 to 35a5 and 35b1 to 35b5 may be arranged along the bottom surfaces 34a and 34b of the side walls 31a and 31b of the containment unit 30 (case 31) so as to face the recessed portions 45a1 to 45a5 and 45b1 to 45b5. The recessed portions and the protruding portions provided to face the interspaces between the circuit patterns 43a1 to 43a10 and 43b1 to 43b7 block silicone gel of the encapsulation material 37 from flowing out of the interspaces between the circuit patterns 43a1 to 43a10 and 43b1 to 43b7 and thereby unfailingly prevent the outflow of the silicone gel.

### Second Embodiment

In a second embodiment, the shapes of the recessed portions (and the protruding portions) formed in the insulating plate 41 of the multi-layer substrate 40 (and the case 31) are different from those of the first embodiment.

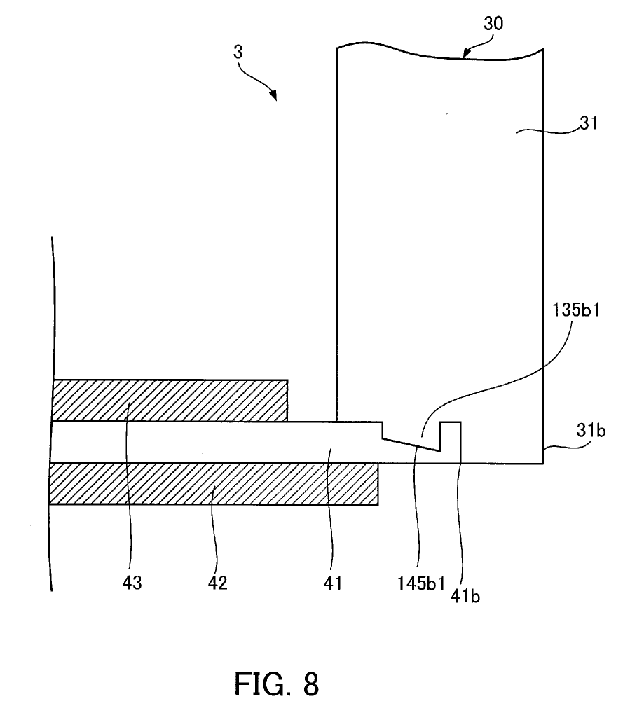

A semiconductor device of the second embodiment will be described with reference to FIG. 8.

FIG. 8 is an enlarged view of a main part of the semiconductor device of the second embodiment.

Note that FIG. 8 is an enlarged view of a part corresponding to the protruding portion 35b1 inserted into the recessed portion 45b1 in the cross-sectional view illustrated in FIG. 5.

The semiconductor device 3 includes a semiconductor module and a cooling unit in the same way as the semiconductor device 1 of the first embodiment and forms a similar configuration as the semiconductor device 1.

The semiconductor device 3 includes a recessed portion 145b1 formed around the center portion of the long side 41b of the insulating plate 41 and a protruding portion 135b1 formed around the center portion of the side wall 31b of the case 31, at least. As illustrated in FIG. 8, an inclined surface that becomes deeper from the circuit plate 43 toward the long side 41b is formed in the bottom of the recessed portion 145b1. An inclined surface that becomes higher from the circuit plate 43 toward the long side 41b is formed at the distal end of the protruding portion 135b1 inserted into the recessed portion 145b1.

The semiconductor device 3 may be provided with recessed portions, in addition to the recessed portion 145b1, along the long side 41b at the periphery portion of the insulating plate 41. Recessed portions may be provided along the long side 41a opposite to the long side 41b. The recessed portions provided along the long side 41b may have bottoms having inclined surfaces that become deeper from the circuit plate 43 toward the long side 41b. The recessed portions provided along the long side 41a may have bottoms having inclined surfaces that become deeper from the circuit plate 43 toward the long side 41a. In addition to the protruding portion 135b1, protruding portions may be provided on the bottom surface of the side wall 31b of the case 31. Protruding portions may also be provided on the bottom surface of the side wall 31a opposite to the side wall 31b. The protruding portions of the side wall 31b may have distal ends having inclined surfaces that become higher from the circuit plate 43 toward the long side 41b. The protruding portions of the side wall 31a may have distal ends having inclined surfaces that become higher from the circuit plate 43 toward the long side 41a.

The semiconductor device 3 includes the recessed portion 145b1 and the protruding portion 135b1 in which the inclined surfaces are formed, and thus the multi-layer substrate 40 is prevented from deforming with the metal plate 42 side protruding downward due to heat stress. Hence, in the semiconductor device 3, greater joining force is generated between the insulating plate 41 and the containment unit 30 (case 31), as compared with the semiconductor device 1 of the first embodiment. Thereby, the semiconductor device 3 prevents the generation of the gaps between the insulating plate 41 and the containment unit 30 (case 31), and prevents the outflow of the silicone gel of the encapsulation material. Also, outside moisture is prevented from flowing into the containment unit 30 (case 31) and reaching the epoxy resin of the encapsulation material. In this way, the semiconductor device 3 prevents the decrease of reliability.

The semiconductor module of the above configuration prevents the decrease of reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor module comprising:
a multi-layer substrate including
an insulating plate being rectangular and including a front surface, a back surface opposite to the front surface, a first long side, a second long side opposite to the first long side, a first recessed portion located in the front surface along the first long side, and a second recessed portion located in the front surface along the second long side, and
a circuit plate located on a region inside a periphery portion of the insulating plate, the periphery portion including the first recessed portion and the second recessed portion;
a case including a first side wall, a second side wall opposite to the first side wall, a third side wall located between the first side wall and the second side wall, a fourth side wall opposite to the third side wall, a first protruding portion located on a bottom surface of the first side wall, a second protruding portion located on a bottom surface of the second side wall, and fixation portions located on the third side wall and the fourth side wall to fix a cooling unit on the back surface of the insulating plate, the case being located on the periphery portion with bonding adhesive in between the case and the periphery portion; and
encapsulation material that encapsulates the circuit plate in the case,
wherein the first protruding portion is inserted in the first recessed portion, and the second protruding portion is inserted in the second recessed portion.

2. The semiconductor module according to claim 1, wherein
the first protruding portion is press-fitted in the first recessed portion, and the second protruding portion is press-fitted in the second recessed portion.

3. The semiconductor module according to claim 1, wherein
the first protruding portion is bonded to the first recessed portion with bonding adhesive, and the second protruding portion is bonded to the second recessed portion with bonding adhesive.

4. The semiconductor module according to claim 1, wherein
the first recessed portion is located at a center portion of the first long side, and the second recessed portion is located at a center portion of the second long side.

5. The semiconductor module according to claim 1, wherein
the first recessed portion is provided in plurality, and the plurality of first recessed portions include a third recessed portion and a fourth recessed portion,
the second recessed portion is provided in plurality, and the plurality of second recessed portions include a fifth recessed portion and a sixth recessed portion,
the first protruding portion is provided in plurality, and the plurality of first protruding portions include a third protruding portion and a fourth protruding portion,
the second protruding portion is provided in plurality, and the plurality of second protruding portions include a fifth protruding portion and a sixth protruding portion,
the third protruding portion is inserted in the third recessed portion,
the fourth protruding portion is inserted in the fourth recessed portion,
the fifth protruding portion is inserted in the fifth recessed portion, and
the sixth protruding portion is inserted in the sixth recessed portion.

6. The semiconductor module according to claim 5, wherein
the third recessed portion is located at a center portion of the first long side,
the fourth recessed portion is located closer to an end portion of the first long side than the third recessed portion,
the third recessed portion is larger in volume than the fourth recessed portion,
the fifth recessed portion is located at a center portion of the second long side,
the sixth recessed portion is located closer to an end portion of the second long side than the fifth recessed portion, and
the fifth recessed portion is larger in volume than the sixth recessed portion.

7. The semiconductor module according to claim 6, wherein
the third recessed portion and the fourth recessed portion have an identical depth,
the third recessed portion is wider than the fourth recessed portion,
the fifth recessed portion and the sixth recessed portion have an identical depth, and
the fifth recessed portion is wider than the sixth recessed portion.

8. The semiconductor module according to claim 1, wherein
the circuit plate includes a plurality of circuit patterns located on the region with margins between the circuit patterns and the first long side and the second long side.

9. The semiconductor module according to claim 8, wherein
the first recessed portion and the second recessed portion are located to face interspaces between the circuit patterns.

10. The semiconductor module according to claim 1, wherein
the first recessed portion and the second recessed portion include bottoms with inclined surfaces that become deeper from an inside area of the insulating plate toward an outside area of the insulating plate.
